(19) United States
(12) Patent Application Publication
(10) Pub. No.: US 2009/0141437 A1
(43) Pub. Date: Jun. 4, 2009

(54) SYSTEM AND METHOD TO ATTACH BEZEL TO DISPLAY PANEL

(75) Inventors: Scott F. Geiger, San Mateo, CA (US); Paul Michael Welch, Cupertino, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: HEWLETT-PACKARD DEVELOPMENT COMPANY, L.P., Fort Collins, CO (US)

(21) Appl. No.: 11/948,909

(22) Filed: Nov. 30, 2007

(51) Int. Cl. H05K 5/00; B23P 11/00

(52) U.S. Cl. 361/679.21; 29/428

(57) ABSTRACT

There is provided a system and method for securing a display to a display bezel. One or more display fasteners snap with mating snap features on the display bezel. One or more mating snap features of the display in turn snap with the display fasteners, thereby securing the display bezel to the display. Furthermore, the display fasteners are swappable and can alter the receiving dimensions of the display bezel, thereby enabling displays of varying dimensions to be inserted into a single display bezel.

### BACKGROUND

This section is intended to introduce the reader to various aspects of art, which may be related to various aspects of the present invention that are described or claimed below. This discussion is believed to be helpful in providing the reader with background information to facilitate a better understanding of the various aspects of the present invention. Accordingly, it should be understood that these statements are to be read in this light, and not as admissions of prior art.

Flat panel displays, such as plasma and liquid crystal displays, are often secured to a bezel then attached to a housing that stores the electronics used to operate the display. Unfortunately, existing bezels do not adequately accommodate displays of different dimensions, e.g., length, width, and/or height. Thus, bezels may be made for each particular display size, which can be quite costly due to the bezel tooling. In addition, the fasteners used to secured displays to bezel generally increase costs due to installation time, labor, tooling, and so forth.

Existing bezels may be secured to the display via screws or snap tabs integral to the bezel. For example, the display may include a frame, such as a sheet metal frame, with screw holes. A screwdriver is used to thread screws into the bezel and the screw holes in the display frame to secure the bezel to the display. This attachment method is time-consuming and labor intensive due to the use of a tool (i.e., screwdriver) and independent attachment of each screw. Alternatively, the bezel may include integral snap tabs to secure the display. This attachment method presents further drawbacks. For example, the costs are quite high for machining and tooling the bezel with integral snap tabs, and the bezel materials are limited to those suitable for snap tabs. In other words, the bezel and integral snap tabs are made of a single material. In addition, replacement displays often do not have the same dimensions as an original display. As a result, the bezel supporting the original display may not be able to support the replacement display.

### BRIEF DESCRIPTION OF THE DRAWINGS

Advantages of one or more disclosed embodiments may become apparent upon reading the following detailed description and upon reference to the drawings in which:

FIG. 1 is a perspective view of a display fastener securing a display panel to a bezel in accordance with an embodiment of the present invention;

FIG. 2 is a top view of an embodiment of the display fastener of FIG. 1;

FIG. 3 is a front view of an embodiment of the display fastener of FIG. 1;

FIG. 4 is a side view of an embodiment of the display fastener of FIG. 1;

FIG. 5 is a rear view of an embodiment of the display fastener of FIG. 1;

FIGS. 6-7 are perspective views of an embodiment of the display fastener and bezel of FIG. 1; and

FIG. 8 is a perspective view of an embodiment of a display panel being inserted into the bezel of FIG. 1; and

FIG. 9 is a flow chart of an embodiment of a process for installing a display panel in a bezel.

### DETAILED DESCRIPTION OF SPECIFIC EMBODIMENTS

One or more exemplary embodiments of the present invention will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

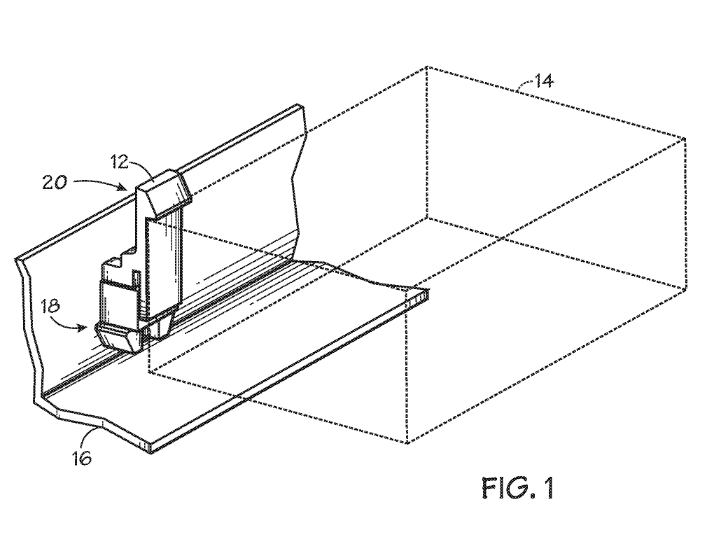

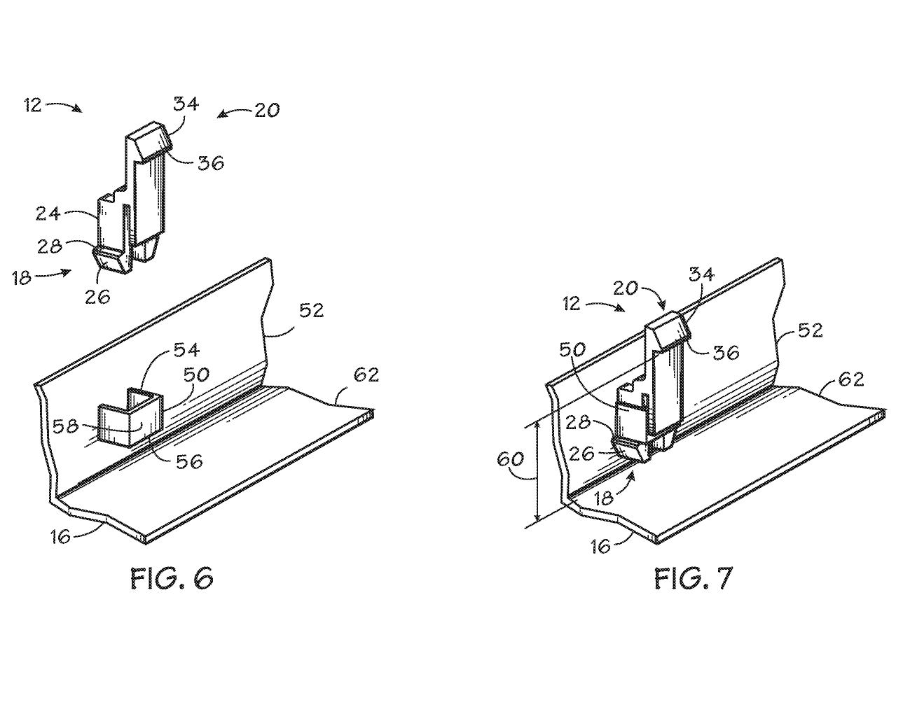

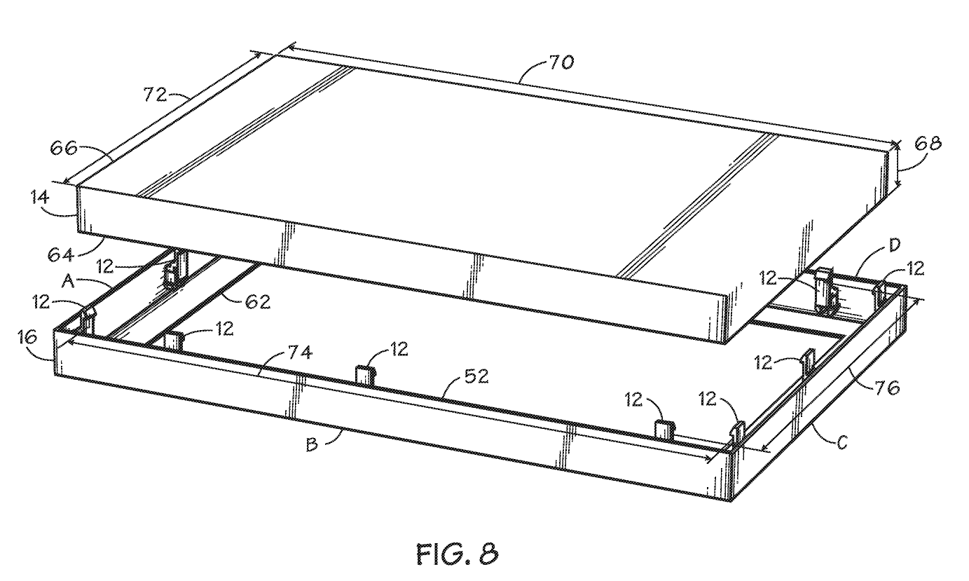

FIG. 1 is a perspective view of a display mounting system 10. In the illustrated embodiment, a display fastener 12 is used to secure a display panel 14 to a bezel 16. The system 10 may be used, for example, to mount a liquid crystal display or a plasma display panel to a television, a computer monitor casing, an all-in-one computer (e.g., single panel enclosure with processor, display, etc.), a table computer, etc. The illustrated display fastener 12 includes a bezel snap region 18 and a display snap region 20. The bezel snap region 18 may be used to secure the display fastener 12 to the bezel 16, as described in more detail below. The display snap region 20 may be used to fasten the bezel 16 to the display panel 14. Although a variety of latches or snaps may be used for both the bezel 16 and the fastener 12, the illustrated snap regions 18 and 20 are male snap features and the bezel 16 includes female snap features (e.g., 50 of FIGS. 6-7). However, these snap regions 18 and 20 may be male and male, female and female, male and female, or female and male, respectively. Advantageously, the snap regions 18 and 20 enable quick mounting of the display panel 14 without the use of tools.

By providing display fasteners 12 separate from the bezel 16, manufacturing costs may be greatly reduced. For example, the cost of machining and tooling the bezel 16 decreases greatly as the design is much simpler. Furthermore, the bezel 16 is not limited to materials which make a good fastener. That is, the display fastener 12 may be composed of a resilient material which allows for elastic deformation, such as, for example, nylon, acrylonitrile butadiene styrene (ABS), or another suitable plastic or metal. The bezel 16 may be composed of a different material from the display fastener 12, such as, for example, a polycarbonate and ABS composite or an acrylic and ABS composite, or may be composed of ABS. Additionally, as described in more detail below, the bezel 16 need not be replaced if a replacement display panel 14 has different dimensions from the original display panel 14. Rather, the display fasteners 12 may be replaced to accommodate the replacement display panel 14.

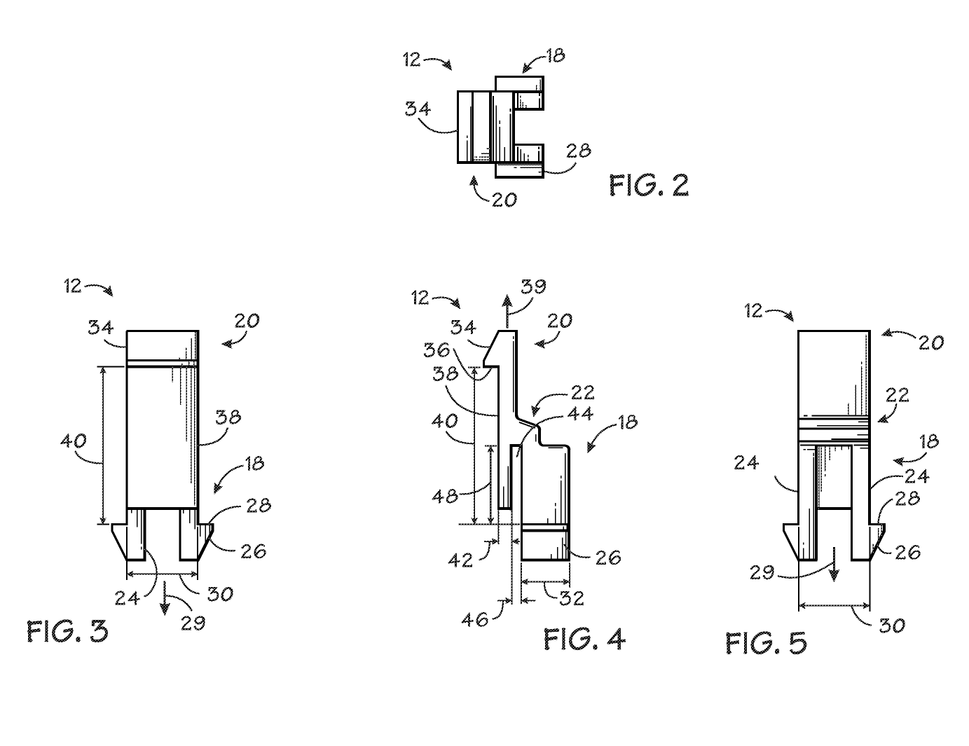

Referring generally to FIGS. 2-5, an embodiment of the display fastener 12 is illustrated in top, front, side, and rear views, respectively. The bezel snap region 18 and the display snap region 20 may be joined together by a junction region 22. The bezel snap region 18 may include two snap components 24. Each snap component 24 includes a cam surface 26 and a locking surface 28. For example, the cam surface 26 may be tapered, angled, or generally wedge-shaped relative to an engagement direction 29. Moreover, the illustrated snap components 24 are oriented such that the cam surfaces 26 face away from one another or generally oppose one another. As will be described in more detail below, the snap components 24 may be deflected toward one another. The locking surfaces 28 operate to secure the display fastener 12 to the bezel 16, as described below. A width 30 and a depth 32 of the bezel snap region 18 may be defined as illustrated.

The display snap region 20 may include a cam surface 34, an engaging surface 36, and a display abutting surface 38, as illustrated in the present embodiment. Again, the cam surface 34 may be tapered, angled, or generally wedge-shaped relative to an engagement direction 39. A fastener length 40 is defined between the engaging surface 36 of the display snap region 20 and the locking surfaces 28 of the bezel snap region 18. As will be described in more detail below, the fastener length 40 may be altered to accommodate display panels of varying depths in the system 10. In addition, a depth 42 of the display snap region 20 may be altered to accommodate display panels of varying facial dimensions (e.g., length and/or width).

Finally, an engaging slot 44 may be defined between the bezel snap region 18 and the display snap region 20. The engaging slot 44 may be characterized by a depth 46. Furthermore, a height 48 of the engaging slot 44 may be defined as the distance from the top of the slot 44 to the locking surface 28 of the bezel snap region 18. The purpose of the engaging slot 44 will become apparent upon further description of the system 10. In another embodiment, the display fastener 12 may not include a portion of the display snap region 20 which protrudes below the junction region 22, thereby eliminating the engaging slot 44.

Turning to FIGS. 6-7, the display fastener 12 is shown in relation to the bezel 16 in accordance with an embodiment of the present invention. Specifically, FIG. 6 illustrates the display fastener 12 exploded from the bezel 16, and FIG. 7 illustrates the display fastener 12 disposed within an engaging member 50 of the bezel 16. The engaging member 50 may be situated on a side wall 52 of the bezel 16. Upon insertion of the display fastener 12 into the engaging member 50, the cam surfaces 26 of the bezel snap region 18 contact a deflecting edge 54 of the engaging member 50 and deflect the snap components 24 toward each other. When the cam surfaces 26 pass a locking edge 56 of the engaging member 50, the snap components 24 return to their original positions. The locking surfaces 28 then abut the locking edge 56, thereby securing the display fastener 12 in the engaging member 50. Furthermore, the width and depth of the bezel snap region 18, as illustrated by the lines 30 and 32, respectively, in FIGS. 3-5, may correspond to an interior width and depth of the engaging member 50 to prevent substantial lateral movement of the display fastener 12 within the engaging member 50. The display fastener 12 may be removed from the engaging member 50 by applying adequate inward pressure to the cam surfaces 26 (e.g., squeezing snap components 24 together) to disengage the locking surfaces 28 from the locking edge 56 and sliding the fastener 12 out of the slot 50.

In accordance with an embodiment of the present technique, the engaging slot 44 may be configured such that, in conjunction with the locking surfaces 28 of the bezel snap region 18, the display fastener 12 is substantially prevented from moving vertically when the fastener 12 is snapped into the engaging member 50. That is, the height of the engaging slot 44, as illustrated by the line 48 in FIG. 4, may correspond to a height of the engaging member 50. In another embodiment, the engaging slot 44 may not be configured to prevent vertical movement of the display fastener 12. Furthermore, the depth 46 of the engaging slot 44 may correspond to the depth of a front wall 58 of the engaging member 50.

Regardless of the configuration of the engaging slot 44, a metric of the display fastener 12 and the bezel 16 may be defined as a bezel/fastener distance 60 from a front wall 62 of the bezel 16 to the engaging surface 36 of the display fastener 12. The bezel/fastener distance 60 may be dictated by the fastener length 40. Again, a variety of different display fasteners 12 may be used with different dimensions to accommodate display panels 14 with different dimensions, thereby substantially reducing the number of different bezels 16.

FIG. 8 is a perspective view of the display panel 14 as it is inserted into the bezel 16. In the illustrated embodiment, several display fasteners 12 are secured to the bezel 16. For example, the illustrated bezel 16 has a rectangular framework with three fasteners 12 distributed along each of the four walls. As the display 14 is lowered into the bezel 16, a leading edge 64 of the display panel 14 acts on the cam surfaces 34 of the display fasteners 12 to elastically deflect the display snap regions 20. Once a rear surface 66 of the display panel 14 passes the engaging surfaces 36 of the display fasteners 12, the display snap regions 20 return to their previous positions, thereby securing the display panel 14 to the bezel 16.

Furthermore, display fasteners 12 may be selected based on the dimensions of the display panel 14 and may be swapped to accommodate displays (e.g., new or replacement) of varying dimensions. The bezel/fastener distance 60 (FIG. 7) may correspond to a depth 68 of the display panel 14. For example, if the display panel 14 has a depth 68 of two inches, the bezel/fastener distance 60 may be approximately two inches, ensuring a secure attachment of the bezel 16 to the display 14. Because the display fastener 12 is removable and replaceable, a fastener 12 having a different fastener length 40 may be used to realize a different bezel/fastener distance 60, thereby allowing for displays of different depths to be installed in the bezel 16.

In addition, the depth 42 of the display engaging region 20 (FIGS. 2-5) may be adjusted according to a width 70 and a length 72 of the display panel 14, as illustrated in FIG. 8. That is, the depth 42 may be increased or decreased to account for small differences in the facial dimensions of different display panels. For example, the illustrated display panel 14 may be disposed between a plurality of display fasteners 12 on opposing side walls 52 of the bezel 16. A distance 74 between display abutting surfaces 38 of opposing fasteners 12 may correspond to the width 70 of the display panel 14. Similarly, a distance 76 between display abutting surfaces 38 of opposing fasteners 12 may correspond to the length 72 of the display panel 14. Accordingly, if a given display panel 14 has a width 70 of 32.7 inches and a length 72 of 24.5 inches, the distances 74 and 76 may be approximately 32.7 inches and 24.5 inches, respectively. This fit ensures that the display panel 14 does not move substantially in relation to the bezel 16. The display panel 14 may be centered in the bezel 16 by using the same display fasteners 12 on opposing side walls 52.

The distances 74 and 76 may be altered without changing the bezel 16 by replacing the fasteners 12 with fasteners having a different display engaging region depth 42. For example, if the display panel 14 is replaced with a display panel 14 having a greater width 70 and a lesser length 72, the display fasteners 12 on sides A and C of the bezel 16 may be replaced with display fasteners 12 having a lesser depth 42 than the previous display fasteners 12, while the display fasteners 12 on sides B and D of the bezel 16 may be replaced with display fasteners 12 having a greater depth 42 than the previous display fasteners 12. Additionally, display fasteners 12 having different display engaging region depths 42 may be used on opposing sides of the bezel 16. That is, the display panel 14 may be slightly off-center in the bezel 16.

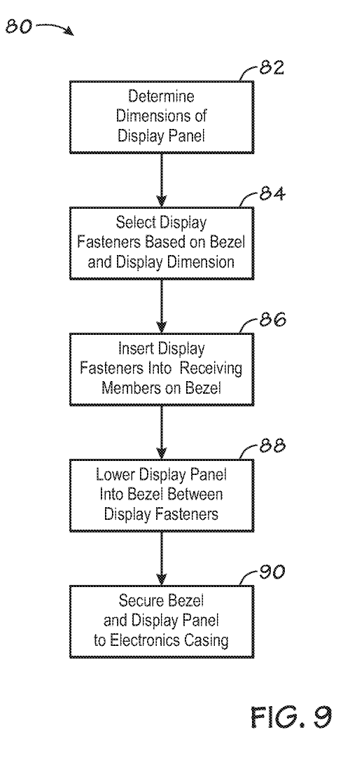

Finally, FIG. 9 illustrates a process 80 by which a display panel 14 may be installed and/or replaced in the bezel 16 using the display fasteners 12 or the like. Discussion of the process 80 refers back to features of the system 10 described in FIGS. 1-8. To install the display panel 14 in the bezel 16, the dimensions of the display panel 14 are first determined (Block 82). The dimensions may include the depth 68, the width 70, and the length 72. The display fasteners 12 are then selected based on the dimensions of the display panel 14 and the bezel 16 (Block 84). Specifically, as described above, the fastener length 40 may be determined based on the depth 68 of the display panel 14 and the position of the engaging member 50 in the bezel 16. Furthermore, the display engaging region depth 42 for the display fasteners 12 on each side wall 52 of the bezel 16 may be determined based on the width 70 and the length 72 of the display panel 14, as described above. The display fasteners 12 are then inserted into the engaging members 50 in the bezel 16 (Block 86). The display panel 14 is lowered into the bezel 16 (Block 88), where it is secured in place by the display fasteners 12.

Once the display panel 14 has been installed in the bezel 16, the system 10 may be secured to a casing containing electronics to operate the display panel 16 (Block 90). The casing may be, for example, a television or a monitor. If the display panel 14 needs to be replaced, the display panel 14 and fasteners 12 may be removed, and the process 80 may be repeated with a new display panel 14.

As appreciated, the fastener 12 may have a variety of latch features and/or snap features (e.g., male or female) for both the bezel snap region 18 and the display snap region 20. Similarly, the display panel 14 and the bezel 16 may have a variety of mating latch features and/or mating snap features (e.g., male or female) to releasably interlock with those of the fastener 12. These latch/snap features may include hooks, slots, catches, receptacles, wedged members, and/or surfaces of the various components. Thus, the disclosed embodiments are not limited to any particular type of latch or snap. However, the separation of the fastener 12 from both the display panel 14 and the bezel 16 enables a wider range of display panels 14 to be mounted in a particular bezel 16.

In addition, the fastener 12 may be used to mount a variety of panels to frames without limitation to displays. For example, the fasteners 12 may be used to mount circuit boards in electronics housings. In the illustrated embodiment, the display panel 14 mounted within the bezel 16 may be part of a television, a computer, a display, or another electronic device. For example, a computer may include the display panel 14, the bezel 16, and the fastener 12 along with a processor, memory, video circuitry, audio circuitry, network circuitry, a disc drive, or a combination thereof, in a single panel shaped housing (e.g., an all-in-one computer, a tablet PC, etc.). In addition, a system having the display panel 14 may further include, connect with, or generally function with a stereo system, speakers, a television receiver, a digital video disc player/recorder, a compact disc player/recorder, a VCR, a video camera, a home theater PC, a game system (e.g., Nintendo Wii, Microsoft Xbox, Sony Playstation, etc.) and various games, a satellite system, a router, or a combination thereof.

While the invention may be susceptible to various modifications and alternative forms, specific embodiments have been shown by way of example in the drawings and are described in detail herein. However, it should be understood that the invention is not intended to be limited to the particular forms disclosed. Rather, the invention is to cover all modifications, equivalents, and alternatives falling within the spirit and scope of the invention as defined by the following appended claims.

What is claimed is:

1. A system, comprising a display fastener having a first snap feature and a second snap feature, wherein the first snap feature is configured to snap with a first mating snap feature of a display bezel, and the second snap feature is configured to snap with a second mating snap feature of a display disposed in the display bezel.

2. The system of claim 1, wherein the second snap feature has a thickness selected to accommodate a first and/or a second dimension of a face of the display.

3. The system of claim 1, wherein a distance between the first and second snap features is selected to accommodate a depth of the display.

4. The system of claim 1, wherein the display fastener comprises nylon.

5. The system of claim 1, wherein the display fastener comprises acrylonitrile butadiene styrene.

6. The system of claim 1, wherein the first snap feature, the second snap feature, or both comprise a male snap member.

7. The system of claim 1, wherein the first snap mating feature comprises a snap receptacle.

8. The system of claim 1, wherein the second mating snap feature comprises a top surface of the display.

9. The system of claim 1, comprising the display mounted to the display bezel via the display fastener.

10. The system of claim 1, comprising a television, a computer, an electronic device, a processor, memory, video circuitry, audio circuitry, network circuitry, a disc drive, a stereo system, speakers, a television receiver, a digital video disc player/recorder, a compact disc player/recorder, a VCR, a video camera, a home theater PC, a game system, a satellite system, a router, or a combination thereof.

11. A system, comprising;
a display bezel comprising a framework configured to support a display, wherein the framework comprises a mating snap feature configured to snap with a first snap feature of a display fastener, such that a second snap feature of the display fastener can snap with a portion of the display.

12. The system of claim 11, comprising the display fastener snapped to the display bezel.

13. The system of claim 12, comprising the display snapped to the bezel via the second snap feature of the display fastener.

14. The system of claim 12, wherein the second snap feature has a thickness selected to accommodate a first and/or a second dimension of a face of the display.

15. The system of claim 12, wherein a distance between the first and second snap features is selected to accommodate a depth of the display.

16. The system of claim 12, wherein the display bezel and the display fastener comprise different materials.

17. The system of claim 11, wherein the bezel comprises polycarbonate, acrylic, acrylonitrile butadiene styrene, or a combination thereof.

18. The system of claim 12, wherein the display fastener comprises nylon.

19. The system of claim 12, wherein the display fastener comprises acrylonitrile butadiene styrene.

20. The system of claim 11, comprising a plurality of the mating snap features on a plurality of side walls of the display bezel.

21. The system of claim 20, comprising a plurality of the display fasteners snapped with the plurality of mating snap features.

22. The system of claim 21, wherein:
the plurality of display fasteners comprises a first set of display fasteners on a first side wall of the display bezel and a second set of display fasteners on a second side wall of the display bezel; and
the first set of display fasteners are the same as the second set of display fasteners.

23. The system of claim 21, wherein:
the plurality of display fasteners comprises a first set of display fasteners on a first side wall of the display bezel and a second set of display fasteners on a second side wall of the display bezel; and
the first set of display fasteners are different from the second set of display fasteners.

24. A method, comprising:
snapping a display fastener to a display bezel; and
snapping a display panel to the display fastener.

25. The method of claim 24, comprising securing the display bezel to the display via a plurality of the display fasteners.

26. The method of claim 24, comprising:
removing the display panel from the display bezel;
selecting a replacement display panel;
selecting a replacement display fastener based on dimensions of the replacement display panel;
snapping the replacement display fastener to the display bezel; and
snapping the replacement display panel to the replacement display fastener.
